(19) United States
(12) Patent Application Publication
(10) Pub. No.: US 2011/0275012 A1
(43) Pub. Date: Nov. 10, 2011

(54) Pellicle

(75) Inventor: Jun Horikoshi, Annaka-shi (JP)

(73) Assignee: SHIN-ETSU CHEMICAL CO., LTD., Tokyo (JP)

(21) Appl. No.: 13/067,018

(22) Filed: May 3, 2011

(30) Foreign Application Priority Data
May 7, 2010 (JP) 2010-107398

(51) Int. Cl. G03F 1/00

(52) U.S. Cl. 430/5

(57) ABSTRACT

There is provided a pellicle in which the agglutinant, that is, the mask-bonding adhesive, is designed to have a light transmission of no greater than 70 percents; preferably the agglutinant is black in color.

The present non-provisional application claims priority under 35 U.S.C. §119(a) from Japanese Patent Application No. 2010-107398 filed on May 7, 2010, the entire disclosure of which is hereby incorporated by reference.

### FIELD OF THE INVENTION

This invention is concerned with a technology for manufacturing a pellicle for lithography used as a dust-fender for masks employed in lithographic printing to manufacture semiconductor devices, printed wiring board, and liquid crystal display board and, in particular, concerns with a pellicle having an agglutinant of a particular characteristic.

### TECHNICAL BACKGROUND OF THE INVENTION

In manufacturing semiconductor devices such as LSI and super-LSI or in manufacturing a liquid crystal display board or the like, a pattern is made by irradiating light to a semiconductor wafer or an original plate for liquid crystal, but if a dust gets to adhere to a photo mask or a reticle (hereinafter merely referred to as a “mask” for simplicity) during the irradiation operation, the dust absorbs light or refracts it, causing deformation of a transferred pattern, roughened edges or black stains on a base, and leads to problems such as damaged dimensions, poor quality, and deformed appearance.

Thus, these works are usually performed in a clean room, but it is still difficult to keep the mask clean all the time. Therefore, a pellicle is tentatively attached to a surface of the mask as a dust-fender before photo irradiation is carried out. Under such circumstances, foreign substances do not directly adhere to the surface of the mask but adhere only to the pellicle membrane, which is sufficiently removed from the mask surface, and thus by setting a photo focus on a lithography pattern on the mask, the foreign substances on the pellicle membrane fail to transfer their shadows on the mask and thus no longer become a cause for problems to the image transfer performance.

In general, a pellicle is built up of a pellicle frame, which is an endless frame bar, and a transparent membrane or pellicle film, the latter being tensely pasted to one of two frame faces. The membrane material is selected from cellulose nitrate, cellulose acetate, fluorine-containing polymer and the like, which transmits lights well, and the pellicle frame is made of aluminum, stainless steel, polyethylene or the like. A solvent capable of dissolving the pellicle membrane is applied to one of the two frame faces of the pellicle frame and the pellicle membrane is laid onto it and the solvent is air-dried to complete the adhesion (see Publication-in-patent 1), or an adhesive such as acrylic resin, epoxy resin or the like is used to adhere the pellicle membrane onto the frame face (hereinafter this face is called “upper frame face”) (See Publication-in-patent 2 and Publication-in-patent 3). The other frame face (hereinafter called “lower frame face”) of the pellicle frame is paved with an agglutinant made of polybutene resin, polyvinyl acetate resin, acrylic resin, silicone resin or the like for attaching the pellicle frame to a mask, and over this agglutinant layer is laid a release sheet (or separator) for protecting the agglutinant layer.

Prior to serving a pellicle on a mask, the release sheet is ripped off and the agglutinant is pressed against the mask surface whereby agglutination takes place. The irradiation of light to create a pattern is conducted while the pellicle is placed beneath the mask, and if not unlucky the pellicle can be serviceable for as long as several years.

Now, after affixing the pellicle to a mask, an inspection for foreign materials is conducted on the pellicle as well as the mask, and when the agglutinant, which connects the pellicle to the mask, is transparent, a foreign material detection equipment is liable to detect a non-existent matter by mistake, especially in the vicinity of the pellicle frame. In fact, a part of the light irradiated from the light source for foreign material detection can become astray as it is refracted and inflected inside the agglutinant layer and can end up inside the detection equipment; wherefore the astray light is recognized as coming from a foreign matter with the result that one erroneous detection count is added.

Then, even when no foreign matter exists either on the pellicle or on the mask, the detector reports an existence of a foreign matter with the consequence of labeling the pellicle and mask set as defective.

### PRIOR ART PUBLICATIONS

[Publication-in-patent 1] Japanese Patent Application Publication S58-219023
[Publication-in-patent 2] U.S. Pat. No. 4,861,402
[Publication-in-patent 3] Japanese Pre-Patent Publication for Public Review S63-27707

### SUMMARY OF THE INVENTION

### Problems the Invention Seeks to Solve

It is therefore an object of the invention, in view of the above circumstances, to find an agglutinant that does not allow light coming to it to stray as it is refracted and inflected against the surface of the agglutinant layer or inside thereof when a pellicle is subjected to a foreign matter optical detection, so that erroneous detection is avoided.

### Means to Solve the Problems

In a pellicle, which is made up chiefly of a pellicle frame having a first frame face and a second frame face, a pellicle membrane bonded to said first frame face, and an agglutinant layer laid over said second frame face as a means for gluing pellicle onto a glass substrate (mask), and a release sheet (or separator) laid over said agglutinant layer, the agglutinant of the agglutinant layer is characterized in that its light transmission is no greater than 70 percents.

It is preferable that the agglutinant is black.

### Effects of the Invention

According to the present invention, by adopting an agglutinant for bonding a pellicle to the mask which has a light transmission of 70 percents or lower, it is possible to increase the yield rate of acceptable pellicles through prevention of wrongful rejection of them based on inadvertent counting of non-existent foreign materials, by virtue of the fact that the light for foreign matter inspection does not penetrate the agglutinant layer and hence is prevented from straying and then entering the foreign matter detector after being refracted and inflected inside the agglutinant layer. When the agglutinant is black, it is possible to further increase the acceptance rate of the pellicle, since the light for foreign matter inspection fails to reflect against the surface of the agglutinant layer.

### BRIEF DESCRIPTION OF THE DRAWINGS

FIG. 1 is a longitudinal cross-sectional view of an embodiment of a pellicle according to the present invention.

### AN EMBODIMENT OF THE INVENTION

Now, the present invention shall be described with reference to the drawing, but it should be understood that the present invention is not limited to it.

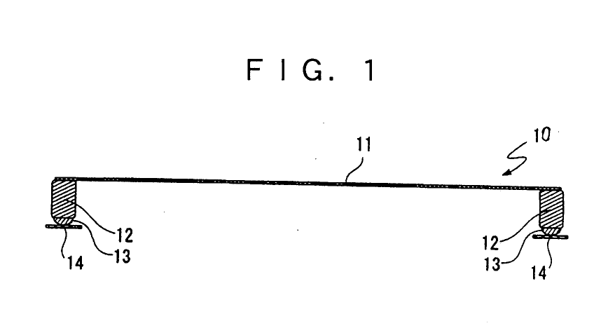

Again, FIG. 1 is a longitudinal cross-sectional view of an embodiment of a pellicle according to the present invention.

In a pellicle 10 of the present invention, a pellicle membrane 11 is tensely pasted over an upper frame face of a pellicle frame 12, which is generally quadrilateral (in particular, rectangular or square) corresponding to the shape of a substrate (photo mask or its glass substrate) to which the pellicle 10 is affixed, and an agglutinant 13 for affixing the pellicle to the substrate is formed on a lower frame face of the pellicle frame 12. In addition, a release sheet (or separator) 14 for protecting the agglutinant 13 is detachably adhered to the lower end face of the agglutinant 13.

As for the material for making the pellicle membrane, there is no particular limit so long as any one conventionally known to be used is selected such as cellulose nitrate, cellulose acetate and fluorine-containing resins, which transmit light well.

There is no particular preference either with regard to the material to make the pellicle frame so long as it is known to have been used and examples are metals such as aluminum and a stainless steel, or synthetic resins such as polyethylene.

In the present invention, the agglutinant is laid on the lower end face of the pellicle frame in a manner such that the agglutinant layer has a predetermined width (which is normally equal to the width of the bar of the pellicle frame, but also can be smaller than that), and that the agglutinant layer extends endlessly through the entire circuit of the lower end face of the pellicle frame so that the pellicle frame is glued to the substrate without a cleft.

As for the agglutinant, any one known to have been conventionally used can be adopted, examples being a polybutene resin, a polyvinyl acetate resin, a silicone resin and an acrylic resin.

The agglutinant should have a light transmission of no greater than 70 percents. This light transmission of the agglutinant is measured by a haze-meter HGM-2 (manufactured by Suga Test Instruments Co., Ltd.). When the light transmission is greater than 70 percents, the light radiated from the foreign material detector turns a stray light after being refracted and inflected inside the agglutinant, and may enter the detector to cause it to mistakenly detect a foreign material. Further, the agglutinant is preferably black in color, for the reason that the light for inspection is less likely to reflect against the surface of the agglutinant.

In order to make an agglutinant to have a light transmission of no greater than 70 percents, one or more of such additives as fumed silica, crystalline silica, sedimentary silica, hollow filler, titanium dioxide, magnesium oxide, zinc oxide, aluminum hydroxide, magnesium hydroxide, magnesium carbonate, calcium carbonate, zinc carbonate, laminated mica, diatomaceous earth, and glass fiber, are added. Also, to blacken the agglutinant, a black pigment or paint such as carbon or iron oxide can be added. The dosages of additives for hazing or blackening should not be so great as to lower the adhesive properties of the agglutinant.

The agglutinant is applied to the lower frame face of the pellicle frame, after being diluted with a solvent if necessary, and then heated to dry till it forms a hard layer. Incidentally, the agglutinant can be applied in ways such as brush coating, spraying and automatic dispensing.

The separator sheet (or release seal), which is for protecting the agglutinant layer until the pellicle is attached to the mask substrate, will have been removed as of the time the pellicle is put to use. Therefore, the release seal is used only where it is necessary to protect the agglutinant layer before the pellicle is put to use. The product pellicle is commonly complete with the release seal (separator sheet). There is no particular requirement for the material of which the release seal is made, so long as any conventionally used material is adopted. Also the method for applying the release seal onto the agglutinant layer may be any that has been conventionally practiced.

### EXAMPLES

Herein below, the present invention shall be explained in detail with reference to the examples and comparative examples, but the examples shall not be construed to limit the scope of the invention.

### Example 1

At first, a rectangular pellicle frame of an aluminum alloy was made by machining, of which the outer periphery measured 782 mm×474 mm, the inner periphery 768 mm×456 mm, and the height 5.0 mm, and of which the corners and edges were rounded to have the inner corner curvature of 2.0 mm radius and the outer corner curvature of 6.0 mm radius; the width of the flat face of the upper and lower frame faces after edge rounding was 4.0 mm. Then, the surface of the frame was subjected to a black almite anodization.

The pellicle frame was transported into a clean room, where it was washed with a neutral detergent and pure water thoroughly and dried.

An agglutinant having a light transmission of no greater than 70 percents was prepared by adding five mass parts of a fumed silica, Musil-120A (manufactured by Shin-Etsu Chemical Co., Ltd.), to 100 mass parts of a silicone adhesive, X-40-3122 (manufactured by Shin-Etsu Chemical Co., Ltd.), and mixing them together. The thus prepared agglutinant was applied to the lower frame face of the pellicle frame.

Thereafter, the agglutinant was dried by air flow until the agglutinant stopped flowing; the pellicle frame was heated to a temperature of 130 degrees centigrade by a high frequency induction heating to equipment (not shown), and thus the agglutinant layer was hardened.

Also, a sheet of pellicle membrane was pasted over the upper pellicle frame face by means of a silicone adhesive, KR-3700 (manufactured by Shin-Etsu Chemical Co., Ltd.), and the external portions of the membrane that extend beyond the frame edge were trimmed off by a cutter, whereby a complete pellicle was made.

### Example 2

A pellicle was made in the same manner as in Example 1, except that the agglutinant was prepared by adding a 0.3 mass part of a black carbon paste LIMS Color 02 (manufactured by Shin-Etsu Chemical Co., Ltd), in place of the fumed silica, to the 100 mass parts of silicone adhesive, X-40-3122 (manufactured by Shin-Etsu Chemical Co., Ltd.).

### Example 3

A pellicle was made in the same manner as in Example 1, except that the agglutinant was prepared by adding 3 mass parts of a black iron oxide paste K-COLOR-FE035 (manufactured by Shin-Etsu Chemical Co., Ltd), in place of the fumed silica, to the 100 mass parts of silicone adhesive, X-40-3122 (manufactured by Shin-Etsu Chemical Co., Ltd.).

### Example 4

A pellicle was made in the same manner as in Example 1, except that the agglutinant was prepared by adding a 0.3 mass part of the black carbon paste LIMS Color 02 (manufactured by Shin-Etsu Chemical Co., Ltd) to 100 mass parts of acrylic resin adhesive by the name of SK-1425 (manufactured by Soken Chemical & Engineering Co., Ltd.).

### Comparative Example 1

A pellicle was made in the same manner as in Example 1, except that the silicone adhesive X-40-3122 (manufactured by Shin-Etsu Chemical Co., Ltd.) was used as it is as the agglutinant.

The results of the estimation of Examples 1-4 and Comparative Example 1 are shown in Table 1.

### [Appearance]

The appearance in color of the agglutinants as prepared in Examples 1-4 and Comparative Example 1 was observed by eye.

### [Light Transmission]

The light transmission was observed of the agglutinants as prepared in Examples 1-4 and Comparative Example 1 after they were hardened and formed into sheets of a size 50 mm×50 mm×2 mm, by means of the haze-meter HGM-2 (manufactured by Suga Test Instruments Co., Ltd.).

### [Foreign Material Inspection]

Foreign materials were inspected for across the surface of the pellicle membrane of the pellicles as made in Examples 1-4 and Comparative Example 1. In order to identify any erroneous detection, observation was repeated after changing the irradiation angle of the light source of the foreign material detector.

TABLE 1
Observation and Estimation of Examples
1-4 and Comparative Example 1

| | Exam- | Exam- | Exam- | Exam- | Comparative |
|---|---|---|---|---|---|
| | ple 1 | ple 2 | ple 3 | ple 4 | Example 1 |
| Appearance | opal | black | black | black | colorless and |
| in Color of | | | | | transparent |
| agglutinants | | | | | |
| Light | 50 | 0 | 0 | 0 | 90 |
| trans- | | | | | |
| mission (%) | | | | | |
| Foreign | no error | no error | no error | no error | error |
| Materials | detec- | detec- | detec- | detec- | detection |
| Inspection | tion | tion | tion | tion | indentified |
| Overall | Good | Good | Good | Good | No Good |
| Estimation | | | | | |

From the results as entered in Table 1, it was confirmed that through a use of an agglutinant of the present invention, it is possible to prevent erroneous detection of foreign materials and thus to prevent lowering of the product yield.

### EXPLANATION FOR REFERENCE NUMERALS

10: pellicle
11: pellicle membrane
12: pellicle frame
13: agglutinant
14: release sheet (separator)

What is claimed is:

1. A pellicle comprising a pellicle frame having a first frame face and a second frame face, a pellicle membrane bonded to said first frame face, and an agglutinant layer laid over said second frame face as a means for gluing pellicle onto a flat substrate, and a release sheet laid over said agglutinant layer, characterized in that the agglutinant layer has a light transmission of no greater than 70 percents.

2. A pellicle as claimed in claim 1, wherein the agglutinant layer is black in color.
